(19) United States
(12) Patent Application Publication
(10) Pub. No.: US 2008/0157879 A1
(43) Pub. Date: Jul. 3, 2008

(54) Decreasing frequency synthesizer lock time for a phase locked loop

(76) Inventors: Dmitry Petrov, Chandler, AZ (US); Robert W. Santucci, Gilbert, AZ (US)

Correspondence Address: SETH KALSON;c/o INTELLEVATE, LLC, P.O. BOX 52050, MINNEAPOLIS, MN, 55402, US

(21) Appl. No.: 11/646,716

(22) Filed: Dec. 28, 2006

(51) Int. Cl. H03L 7/093; H03L 7/089

(52) U.S. Cl. 331/16

(57) ABSTRACT

In an embodiment, a phase locked loop in which leakage current provided to a loop filter of the phase locked loop is adaptive during a calibration procedure involving more than one lock period. In some embodiments, a controller reads the leakage current from a look-up table. For some embodiments, reading the look-up table at a particular lock period depends upon a comparison of a reference voltage to a quantity, where the reference voltage is used in the loop filter to set the range of a control voltage on the voltage-controlled oscillator of the phase locked loop, and the quantity to which the reference voltage is compared is a measurement of the control voltage at a previous lock period. Other embodiments are described and claimed.

### FIELD

The invention relates to circuits, and more particularly, to phase locked loops.

### BACKGROUND

In some applications, calibrating a phase locked loop involves measuring the tuning gain of the voltage-controlled oscillator in the phase locked loop. The tuning gain may be measured by observing the rate of change in oscillation frequency to a change in control voltage on the voltage-controlled oscillator in the phase locked loop. Such measurement procedures run the phase locked loop through several lock periods at different frequencies. Decreasing the time of a lock period, that is, the time it takes for a phase locked loop to lock onto a new frequency, leads to a decrease in the total calibration time.

### BRIEF DESCRIPTION OF THE DRAWINGS

FIG. 1 illustrates a phase locked loop according to an embodiment of the present invention.

FIG. 2 illustrates a charge pump and loop filter according to an embodiment of the present invention.

FIG. 3 illustrates a computer system employing an embodiment of the present invention.

### DESCRIPTION OF EMBODIMENTS

In the descriptions that follow, the scope of the term “some embodiments” is not to be so limited as to mean more than one embodiment, but rather, the scope may include one embodiment, more than one embodiment, or perhaps all embodiments.

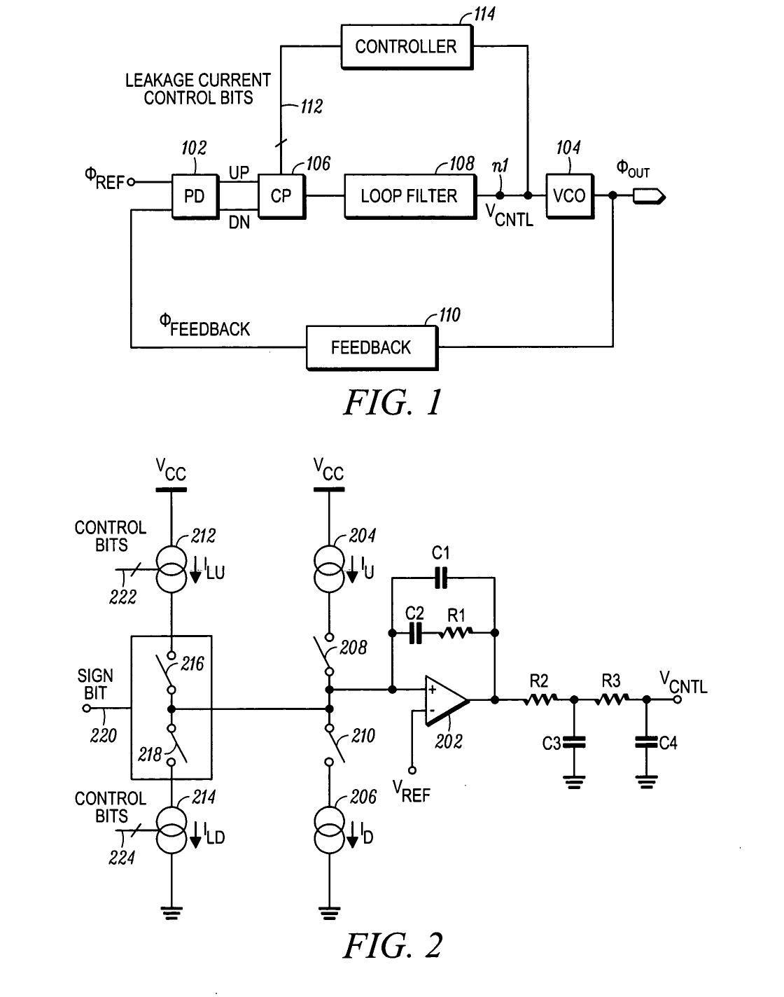

Phase looked loops (PLLs) are employed in many systems. For example, a PLL may provide a clock signal for digital logic circuits to sample a received data signal, to provide a mixing signal to down-convert a received radio frequency signal, or to provide a carrier signal upon which information is modulated, to name just a few examples. FIG. 1 illustrates, at a functional block level, a phase locked loop to provide an output signal φ_{OUT} having a frequency that is related to the frequency of input signal φ_{REF} by an integer or rational number. Signals φ_{REF} and φ_{FEEDBACK} are provided as input to phase detector (PD) 102. In the example of FIG. 1, reference signal φ_{REF} is a fixed signal and the feedback-divide ratio is being controlled by a sigma-delta modulator so that the PLL is used as a frequency synthesizer. In other applications, such as when the PLL is used to generate a clock signal to sample received data, reference signal φ_{REF} may be the output signal of a clock receiver. In FIG. 1, feedback circuit 110 and VCO 104 are controlled by controller 114 as well.

PD 102 provides UP and DN signals, depending upon the relationship between signals φ_{REF} and φ_{FEEDBACK}. Various implementations of how the two input signals are compared by a phase detector may be employed, and various conventions may be followed by which the oscillation frequency of voltage controlled oscillator (VCO) 104 is controlled as a function of the relationship between signals φ_{REF} and φ_{FEEDBACK}.

For example, for some embodiments, if feedback signal φ_{FEEDBACK}. as indicated in FIG. 1, lags reference signal φ_{REF}, then UP signal will have wider pulses than that of DN signal, and UP signal will having a rising transition preceding the rising transition of DN signal. Conversely, if feedback signal φ_{FEEDBACK} leads reference signal φ_{REF}, then DN signal will have wider pulses than that of UP signal, and its upward transitions will precede that of UP signal. UP and DN signals are provided to charge pump 106 so that charge is sourced into loop filter 108 during those time intervals for which UP signal has wider pulses than that of DN signal, and charge is sunk from loop filter 108 during those time intervals for which DN signal has wider pulses than that of UP signal.

The oscillation frequency of VCO 104 is a function of several parameters, one of which is control voltage V_{CNTL} at node n1. Loop filter 108 may be designed such that if charge pump 106 sources current to loop filter 108, control voltage V_{CNTL} at node n1 is raised, and if charge pump 106 sinks current from loop filter 108, control voltage V_{CNTL} is lowered. VCO 104 may be designed so that its oscillation frequency increases as control voltage V_{CNTL} increases. Output signal φ_{OUT} is provided as an input signal to feedback circuit 110, which provides feedback signal φ_{FEEDBACK} as its output signal. For synthesizers in which feedback circuit 110 effectively performs a division by a rational number R, where R is greater than one, the frequency of φ_{FEEDBACK} is the frequency of output signal φ_{OUT} divided by R, and as a result of the feedback path providing feedback signal φ_{FEEDBACK}, when steady state lock is reached, output signal φ_{OUT} has a frequency R times that of the frequency of reference signal φ_{REF}.

In some block level descriptions of phase locked loops, the charge pump and loop filter are often combined into one functional block labeled as the loop filter. For convenience, FIG. 1 shows CP 106 as a functional block separate from loop filter 108. CP 106 includes a current source and a current sink for providing leakage current, where the magnitude, and algebraic sign (i.e., whether current is sourced or sunk), is controlled by a set of control bits on interface 112.

The addition of leakage current fine tunes the current provided by charge pump 106, and may be used to speed up lock of a PLL during a calibration procedure based on estimating the tuning gain of VCO 104. The tuning gain is the ratio of the change in oscillation frequency to the change in control voltage, e.g., Δf/ΔV_{CNTL}, where Δf is a change in oscillation frequency of VCO 104 due to a change ΔV_{CNTL} in control voltage. Knowledge of the tuning gain helps in setting various parameters, such as the magnitude of the source and sink currents provided by a charge pump. In many systems, when the PLL is powered up, or when the a different frequency is to be synthesized, such as for example by changing the rational number R associated with feedback circuit 110, a new estimate of the tuning gain is obtained. One method for calibrating a phase locked loop based on estimating the tuning gain is described in U.S. Pat. No. 6,724,265, “Compensation for Oscillator Tuning Gain Variations in Frequency Synthesizers,” by S. R. Humphreys. In estimating the tuning gain, various frequencies are synthesized, and measurements of the change in voltage and change in oscillation frequency are made when the PLL has locked on the various frequencies. Speeding up the rate at which the PLL locks leads to a speed up for calibration procedures based on estimating the tuning gain.

An embodiment comprising a fourth order loop filter, including charge pump, is illustrated in FIG. 2. OPAMP (Operational Amplifier) 202, capacitors C1, C2, and C3, and resistors R1, R2, and R3, together comprise an active fourth order filter. These capacitors and resistors may be variable. Current source 204 sources the UP current I_{U} to the fourth order loop filter in response to the UP signal of PD 102 closing switch 208, and current sink 206 sinks the DN current I_{D} from the fourth order loop filter in response to the DN signal of PD 102 closing switch 210. The magnitudes of the currents I_{U} and I_{D} may be set by control bits adjusting current source 204 and current sink 206, but for ease of illustration such control bits are not explicitly indicated in FIG. 2.

A source leakage current, indicated as I_{LU} in FIG. 2, is sourced by current source 212, and a sink leakage current, indicated as I_{LD}, is sunk by current sink 214. An algebraic sign bit controls whether a source leakage current is sourced, or whether a sink leakage current is sunk. As indicated in FIG. 2, switches 216 and 218 are controlled by an algebraic sign bit on interface 220. If the algebraic sign bit denotes a positive sign, then switch 216 is closed and switch 218 is opened, and if the algebraic sign bit denotes a negative sign, then switch 216 is opened and switch 218 is closed.

The magnitude of leakage current I_{LU} (for simplicity, the adjectives “source” and “sink” are dropped) is adjusted by a set of control bits on interface 222, and the magnitude of leakage current I_{LD} is adjusted by a set of control bits on interface 224. These control bits are provided by controller 114, illustrated in FIG. 1, where FIG. 1 shows that controller 114 measures control voltage V_{CNTL}. Controller 114 includes an analog-to-digital converter to digitize control voltage V_{CNTL}, and may be implemented by a digital signal processor.

During the calibration procedure, the PLL goes through several loop locks as the synthesized frequency is changed. It is found that adaptively setting the leakage current, instead of fixing it throughout the duration of loop locks, may accelerate the time needed for loop locks. That is, the loop lock times may be decreased, so that there is a reduction in the measurement time for estimating the voltage-controlled oscillator tuning gain.

A look-up table may be employed to adjust the leakage currents. Different look-up tables may be used, depending upon the frequency range. An example of a look-up table for a synthesized frequency in the range of 0.7 GHz to 1.0 GHz is illustrated below as Table 1, where the entries indicate the algebraic sign and magnitude of the leakage currents. In the particular example of Table 1, there are three synthesized frequencies, so that there are three lock periods of time. The leakage current depends upon whether an estimated control voltage V_{CNTL}_{_{—}}_{EST} is greater or less than the reference voltage V_{REF}. The reference voltage is provided at the inverting input port of OPAMP 202 in FIG. 2, and sets the voltage operating range of V_{CNTL}. The estimated control voltage as used in Table 1 for a given lock period is the estimate of the settled control voltage at the end of the lock period. Because this is not known at the beginning of a lock period, some advance knowledge or estimate of the settled control voltage is used to determine which row of Table 1 is referenced to provide the value of the leakage current.

An estimate of the settled control voltage for a given lock period may be attained from the results of the previous lock period. Note that for the first lock period, the leakage current is set to zero regardless of whether the settled control voltage is less or greater than the reference voltage. Because a tight lock is not required during the first lock period, the phase detector may operate in its dead zone so that the leakage current may be set to zero as indicated in Table 1. After the first lock period, the difference between the settled control voltage and the reference voltage may be measured by controller 114 to determine whether the settled control voltage is less or greater than the reference voltage. This difference in the settled control voltage and the reference voltage may be used for the remaining lock periods, so that the desired leakage current may be determined.

TABLE 1

| | First Lock | Second Lock | Final Lock |
|---|---|---|---|
| V_{CNTL}_{_{—}}_{EST} > V_{REF} | 0 | 5% UP current | 10% UP current |
| V_{CNTL}_{_{—}}_{EST} < V_{REF} | 0 | 5% DN current | 10% DN current |

Leakage current for 0.7 to 1.0 GHz synthesizer range

The entries in Table 1 provide both the algebraic sign and magnitude. For example, if in the second lock period the condition V_{CNTL}_{_{—}}_{EST}>V_{REF} is satisfied, then the algebraic sign is positive and the magnitude of the leakage current is set to 5% that of the UP current. That is, the leakage current adds to the UP current, which is sourced to the loop filter. But if the condition V_{CNTL}_{_{—}}_{EST}<V_{REF} holds, then the algebraic sign of the leakage current is negative, and the magnitude is 5% that of the DN current. That is, leakage current is added to the DN current, which is sunk from the loop filter.

As another example of a look-up table, Table 2 provides an example in which the synthesizer frequency is in the range of 1.8 GHz to 2.0 GHz. Unlike Table 1, note that in Table 2 the leakage current is non-zero during the first lock period. In an embodiment illustrated by Table 2, either positive or negative charge pump current may be used, so long as it is non-zero for the first lock. This helps increase accuracy of the first voltage estimate for cases in which a finer lock is required. Performance is improved if one can estimate and place the leakage current in the correct direction. For both tables, the magnitude of the leakage current after the final lock period may be given by the expression (2^{N-1}−1)F_{REF}/F_{MIN} multiplied by the UP or DN current, where F_{MIN} is the minimum output frequency of interest, F_{REF} is the synthesizer reference frequency, and N is the number of ratio-control bits in a sigma-delta modulator used in feedback circuit 110, usually 3 or 4 for some embodiments. For the embodiments illustrated by Tables 1 and 2, F_{MIN} may be about 700 MHz or 1700 MHz, respectively, and F_{MAX} may be about 1200 MHz or 2500 MHz, respectively. In both tables, the equal case where V_{CNTL}_{_{—}}_{EST}=V_{REF}, isn't displayed. In practice, if equality is determined, then either entry in the current lock period column may be chosen.

TABLE 2

| | First Lock | Second Lock | Third Lock | Final Transmission |
|---|---|---|---|---|
| V_{CNTL}_{_{—}}_{EST} > V_{REF} | 2.5% UP | 5% UP current | 20% UP current | (2^{N-1} − 1)F_{REF}/F_{MIN} |
| | current | | | UP Current |
| V_{CNTL}_{_{—}}_{EST} < V_{REF} | 2.5% DN | 5% DN current | 20% DN current | (2^{N-1} − 1)F_{REF}/F_{MIN} |
| | current | | | DN Current |

Leakage current for 1.8 to 2.0 GHz synthesizer range

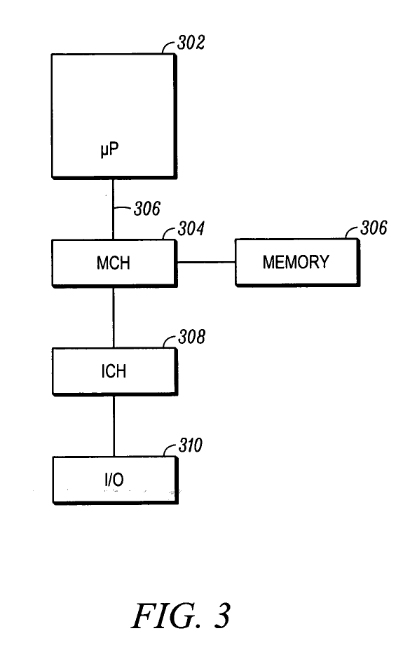

It is expected that embodiments of the present invention may find wide application to a number of systems. One such system is a computer system, which is illustrated in simplified form in FIG. 3. In FIG. 3, microprocessor 302 communicates to memory controller hub (MCH) 304 by way of front side bus 306. MCH 304 provides communication to system memory 306, as well as to input/output controller hub (ICH) 308. ICH 308 provides communication to various input/output devices, collectively represented by the functional block 310. The system diagram of FIG. 3 is simplified, and not all system blocks are shown. Embodiments of the present invention may find application in some or all of the various functional blocks illustrated in FIG. 3. In particular, embodiments may find application in MCH 304, sometimes referred to as a chipset, or part of a chipset. This embodiment may be used to improve jitter performance of a chipset serial link.

For some systems, various circuits, such as a PLL, may be put into a sleep mode to save energy. When a PLL is taken out of its sleep mode, fast lock is desirable, so that embodiments may be of utility to achieve faster calibration of a PLL when taken out of its sleep mode.

Various modifications may be made to the disclosed embodiments without departing from the scope of the invention as claimed below.

It is to be understood in these letters patent that the meaning of “A is connected to B”, where A or B may be, for example, a node or device terminal, is that A and B are connected to each other so that the voltage potentials of A and B are substantially equal to each other. For example, A and B may be connected together by an interconnect (transmission line). In integrated circuit technology, the interconnect may be exceedingly short, comparable to the device dimension itself. For example, the gates of two transistors may be connected together by polysilicon, or copper interconnect, where the length of the polysilicon, or copper interconnect, is comparable to the gate lengths. As another example, A and B may be connected to each other by a switch, such as a transmission gate, so that their respective voltage potentials are substantially equal to each other when the switch is ON.

It is also to be understood in these letters patent that the meaning of “A is coupled to B” is that either A and B are connected to each other as described above, or that, although A and B may not be connected to each other as described above, there is nevertheless a device or circuit that is connected to both A and B. This device or circuit may include active or passive circuit elements, where the passive circuit elements may be distributed or lumped-parameter in nature. For example, A may be connected to a circuit element that in turn is connected to B.

It is also to be understood in these letters patent that a “current source” may mean either a current source or a current sink. Similar remarks apply to similar phrases, such as, “to source current”. That is, the term “source” when used in reference to a current may encompass either sourcing the current or sinking the current.

It is also to be understood in these letters patent that various circuit blocks, such as current mirrors, amplifiers, etc., may include switches so as to be switched in or out of a larger circuit, and yet such circuit blocks may still be considered connected to the larger circuit because the various switches may be considered as included in the circuit block.

Various mathematical relationships may be used to describe relationships among one or more quantities. For example, a mathematical relationship or mathematical transformation may express a relationship by which a quantity is derived from one or more other quantities by way of various mathematical operations, such as addition, subtraction, multiplication, division, etc. Or, a mathematical relationship may indicate that a quantity is larger, smaller, or equal to another quantity. These relationships and transformations are in practice not satisfied exactly, and should therefore be interpreted as “designed for” relationships and transformations. One of ordinary skill in the art may design various working embodiments to satisfy various mathematical relationships or transformations, but these relationships or transformations can only be met within the tolerances of the technology available to the practitioner.

Accordingly, in the following claims, it is to be understood that claimed mathematical relationships or transformations can in practice only be met within the tolerances or precision of the technology available to the practitioner, and that the scope of the claimed subject matter includes those embodiments that substantially satisfy the mathematical relationships or transformations so claimed.

What is claimed is:

1. An apparatus comprising:
a voltage-controlled oscillator having an oscillation frequency dependent on a control voltage;
a phase detector to provide an UP signal and a DN signal;
a loop filter to provide the control voltage to the voltage-controlled oscillator; and
a charge pump to source an UP current to the loop filter if the phase detector outputs the UP signal, and to source a DN to the loop filter if the phase detector outputs the DN signal, and to source to the loop filter a first leakage current during a first lock period and a second leakage current during a second lock period, where the second leakage current has a value different from that of the first leakage current.

2. The apparatus as set forth in claim 1, the loop filter having a reference voltage, wherein the second leakage current has an algebraic sign dependent upon a relationship between the reference voltage and a second control voltage estimate.

3. The apparatus as set forth in claim 2, where the relationship between the reference voltage and the second control voltage estimate is a function of the difference between the reference voltage and the second control voltage estimate.

4. The apparatus as set forth in claim 2, wherein the first leakage current is set to zero.

5. The apparatus as set forth in claim 2, wherein the first leakage current has an algebraic sign dependent upon a relationship between the reference voltage and a first control voltage estimate.

6. The apparatus as set forth in claim 3, where the relationship between the reference voltage and the first control voltage estimate is a function of the difference between the reference voltage and the first control voltage estimate.

7. The apparatus as set forth in claim 2, wherein the second control voltage estimate is a measurement of the control voltage provided by the loop filter at the end of the first lock period.

8. The apparatus as set forth in claim 7, wherein the first leakage current is set to zero.

9. The apparatus as set forth in claim 8, wherein the first leakage current has an algebraic sign dependent upon a relationship between the reference voltage and a first control voltage estimate.

10. The apparatus as set forth in claim 1, wherein the first lock period is a beginning of a calibration procedure.

11. An apparatus comprising:
a loop filter; and
a controller to adjust a leakage current provided to the loop filter, wherein the leakage current is read from a look-up table.

12. The apparatus as set forth in claim 11, the controller to adjust the leakage current during a first lock period to provide a first leakage current, and to adjust the leakage current during a second lock period to provide a second leakage current.

13. The apparatus as set forth in claim 12, the loop filter comprising an amplifier, the amplifier comprising an input port having a reference voltage, the controller to read the algebraic sign of the second leakage current from the look-up table, where the algebraic sign of the second leakage current depends upon a relationship between the reference voltage and a second control voltage estimate.

14. The apparatus as set forth in claim 13, where the relationship is a function of the difference between the reference voltage and the second control voltage estimate.

15. The apparatus as set forth in claim 13, further comprising:
a voltage-controlled oscillator having an oscillation frequency dependent on a control voltage provided by the loop filter;
where the second control voltage estimate is based on a measurement of the control voltage at the end of the first lock period.

16. The apparatus as set forth in claim 13, the controller to read the algebraic sign of the first leakage current from the look-up table, where the algebraic sign of the first leakage current depends upon a relationship between the reference voltage and a first control voltage estimate.

17. The apparatus as set forth in claim 16, where the relationship between the reference voltage and the first control voltage estimate is a function of the difference between the reference voltage and the first control voltage estimate.

18. The apparatus as set forth in claim 13, wherein the first leakage current is set to zero.

19. A system comprising:
a system memory; and
a chipset in communication with the system memory, the chipset comprising a phase locked loop, the phase locked loop comprising:
a loop filter; and
a controller to adjust a leakage current provided to the loop filter, wherein the leakage current is read from a look-up table.

20. The system as set forth in claim 19, the controller to adjust the leakage current during a first lock period to provide a first leakage current, and to adjust the leakage current during a second lock period to provide a second leakage current; and
the loop filter comprising an amplifier, the amplifier comprising an input port having a reference voltage, the controller to read the algebraic sign of the second leakage current from the look-up table, where the algebraic sign of the second leakage current depends upon a relationship between the reference voltage and a second control voltage estimate.
